(19) United States
(12) Patent Application Publication
(10) Pub. No.: US 2014/0198450 A1
(43) Pub. Date: Jul. 17, 2014

(54) POWER CONVERSION DEVICE

(71) Applicants: Ryusuke BABA, Toyota-shi (JP); Yutaka MORIMOTO, Toyokawa-shi (JP); Hitoshi IMURA, Chiryu-shi (JP)

(72) Inventors: Ryusuke BABA, Toyota-shi (JP); Yutaka MORIMOTO, Toyokawa-shi (JP); Hitoshi IMURA, Chiryu-shi (JP)

(73) Assignee: TOYOTA JIDOSHA KABUSHIKI KAISHA, Toyota-shi (JP)

(21) Appl. No.: 14/154,569

(22) Filed: Jan. 14, 2014

(30) Foreign Application Priority Data
Jan. 15, 2013 (JP) 2013-004630

(51) Int. Cl. H05K 7/20; H05K 9/00

(52) U.S. Cl. CPC H05K 7/2089; H05K 9/0007
USPC 361/689

(57) ABSTRACT

A power conversion device includes a laminated unit, a reactor, a shield, and coolant passages. In the laminated unit, flat-plate semiconductor modules housing semiconductor elements and flat-plate cooling plates are laminated. The shield is interposed between the reactor and electronic components. The coolant passages supply coolant to or discharge coolant from the laminated unit. The coolant passages pass through an interior of the shield.

### INCORPORATION BY REFERENCE

The disclosure of Japanese Patent Application No. 2013-004630 filed on Jan. 15, 2013 including the specification, drawings and abstract is incorporated herein by reference in its entirety.

### BACKGROUND OF THE INVENTION

1. Field of the Invention

The present invention relates to a power conversion device.

2. Description of Related Art

An electric vehicle includes a power conversion device that converts direct current power of a battery into alternate current power that is suitable for driving a motor for vehicle travel. A typical power conversion device is an inverter or a voltage converter. Because the power conversion device of the electric vehicle operates with large power, a large amount of heat may generated in the power conversion device. Meanwhile, compactness is demanded for a device for a vehicle. Both heat control and compactness are demanded for the power conversion device for the electric vehicle.

The large amount of heat may generated in devices, such as semiconductor elements and reactors, of the power conversion device. Examples of the semiconductor elements include power transistors such as IGBTs and power elements such as free wheel diodes that are parallelly connected with the power transistors. The reactor constitutes a voltage conversion circuit along with the semiconductor element. Japanese Patent Application Publication No. 2011-228426 (JP 2011-228426 A) suggests the power conversion device that compactly houses the semiconductor element, the reactor, and a cooling apparatus that cools these. The cooling apparatus of the power conversion device has a plurality of cooling plates that are alternately laminated with a plurality of flat-plate semiconductor modules containing semiconductor elements. Such a laminated body will hereinafter be referred to as “laminated unit”. The laminated unit has two coolant passages that pass through the plurality of cooling plates. In the laminated unit of JP 2011-228426 A, a coolant supply pipe and a coolant discharge pipe that are linearly aligned with the coolant passages are connected to the cooling plate positioned at an end in a laminating direction. The coolant supply pipe and the coolant discharge pipe extend in parallel with each other, and the reactor is disposed between the pipes.

Further, Japanese Patent Application Publication No. 2009-261125 (JP 2009-261125 A) discloses a technique related to cooling of the laminated unit and the reactor. A power conversion device of JP 2009-261125 A has the reactor disposed in the vicinity of the above-described coolant supply pipe and coolant discharge pipe. Incidentally, the power conversion device includes a large capacity capacitor for smoothing output current of the battery. In the technique of JP 2009-261125 A, a heat receiving plate is disposed between the reactor and the capacitor, and heat of the heat receiving plate is absorbed by the cooling plates of the laminated unit. Specifically, a heat dissipation plate is interposed between the pair of cooling plate in the laminated unit, and the heat dissipation plate and the heat receiving plate are connected together by a heat pipe. The heat of the capacitor is absorbed by the heat receiving plate, next transmitted to the heat dissipation plate through the heat pipe, and then transmitted to the cooling plates.

### SUMMARY OF THE INVENTION

The present invention relates to cooling of a laminated unit and a reactor and provides a power conversion device that can reduce an influence of heat of the reactor on other electronic components.

A first aspect of the present invention provides a power conversion device including: a laminated unit; a reactor; a shield. In the laminated unit, flat-plate semiconductor modules and flat-plate cooling plates are laminated. The flat-plate semiconductor modules houses semiconductor elements. The shield is interposed between the reactor and electronic components. The shield has coolant passages which supply coolant to or discharge coolant from the laminated unit through the shield. An above configuration allows cooling of the shield by the coolant that passes through the coolant passages and reduction in an influence of heat of the reactor on other electronic components that are positioned on the opposite side of the shield.

In the power conversion device, a portion of the coolant passages may be integral with the shield. An above configuration improves heat transmission efficiency between coolant pipes constituting the coolant passages and the shield. Further, integral molding provides an advantage in an aspect of production cost.

in the power conversion device, the shield may include plurality of plates that are coupled together. In the power conversion device, the shield may contact the reactor. In the power conversion device, the shield contact an end surface of the laminated unit in a laminating direction.

In the power conversion device, the electronic components may be a capacitor module and a control board. The shield may be a cooling block. The cooling block may includes an upper plate and a side plate. The cooling block may has the coolant passages which supply coolant to or discharge coolant from the laminated unit through the coolant passages. The upper plate may be interposed between the reactor and the control board. The side plate may be interposed between the reactor and the capacitor module. In an above configurations, the shield is cooled by the cooling plate at an end of the laminated unit in the laminating direction. Because such shield can transmit heat to both of the cooling plate positioned at the end of the laminated unit and the coolant passages, the reactor can efficiently be cooled.

### BRIEF DESCRIPTION OF THE DRAWINGS

Features, advantages, and technical and industrial significance of exemplary embodiments of the invention will be described below with reference to the accompanying drawings, in which like numerals denote like elements, and wherein:

FIG. 1 is a block diagram of an electric system of a power conversion device in accordance with an embodiment of the present invention;

FIG. 2 is a plan view of the power conversion device of the embodiment;

FIG. 3 is a cross-sectional view taken along line in FIG. 2;

FIG. 4 is a cross-sectional view taken along line IV-IV in FIG. 2;

FIG. 5 is a perspective view showing the positional relationship among a laminated unit, a reactor, a cooling block, and a capacitor module in accordance with the embodiment;

FIG. 6 is a perspective view of the cooling block in accordance with the embodiment as seen from another angle; and

FIG. 7 is a perspective view of the cooling block in accordance with the embodiment as seen from yet another angle.

### DETAILED DESCRIPTION OF EMBODIMENTS

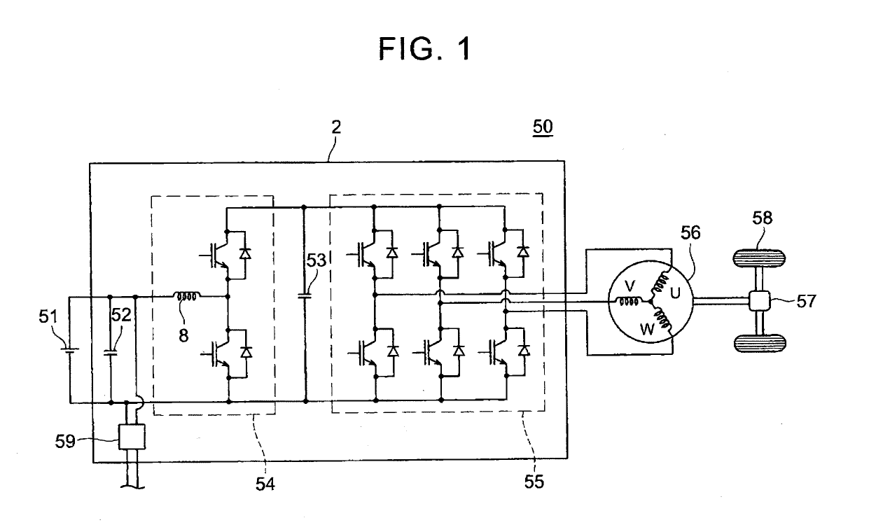

A power conversion device 2 of an embodiment will be described with reference to drawings. The power conversion device 2 is installed in an electric vehicle 50 and converts direct current power of a battery 51 to alternate current power that is suitable for motor drive. An electric system (drive system) of the electric vehicle 50 will be described with reference to FIG. 1. The power conversion device 2 boosts an output voltage of the battery 51 and thereafter converts direct current into alternate current. In other words, the power conversion device 2 includes a booster circuit 54 and an inverter circuit 55. The booster circuit 54 includes various components, such as, two transistors, two diodes, and a reactor 8. These components constitute the booster circuit 54 shown in FIG. 1. A detailed description of a configuration of the booster circuit 54 shown in FIG. 1 will not be made. The power conversion device 2 of the electric vehicle 50 operates with large current. Therefore, a large amount of heat is generated by semiconductors such as the transistors and the reactor 8. The reactor 8 is relatively larger size compared with the other components of the booster circuit 54.

A capacitor 52 for smoothing output current of the battery 51 is connected to an input side of the booster circuit 54. A capacitor 53 for smoothing output current of the booster circuit 54 is connected to an output side of the booster circuit 54, that is, an input side of the inverter circuit 55. Because large current flows through the capacitors 52, 53, the capacitors have large capacities and large physical volumes.

Output of the inverter circuit 55 is supplied to a motor 56. Output torque of the motor 56 is transmitted to drive wheels 58 via a differential gear 57. Although not shown in FIG. 1, the power conversion device 2 includes a control circuit that controls transistors of the booster circuit 54 and the inverter circuit 55. The control device determines a boost ratio of a battery voltage or an output frequency of the inverter circuit according to a vehicle speed or an accelerator position and generates a transistor control signal, that is, a PWM signal corresponding thereto.

A buck converter 59 other than the booster circuit 54 is connected to the battery 51. The buck converter 59 reduces the voltage of the battery 51 to a voltage suitable for an auxiliary device and supplies the voltage thereto. The “auxiliary device” is a generic name for a device such as a room lamp or a car navigation system that operates at a lower voltage than the output voltage of the battery 51 that stores power for travel.

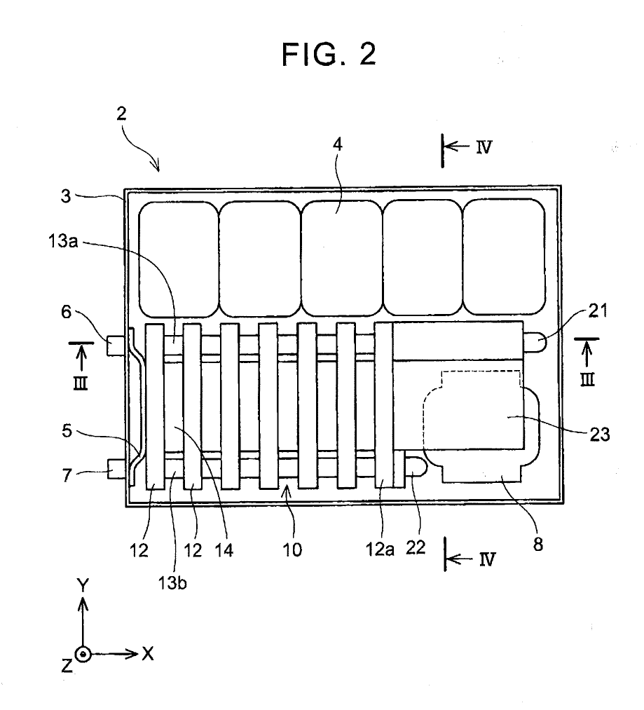

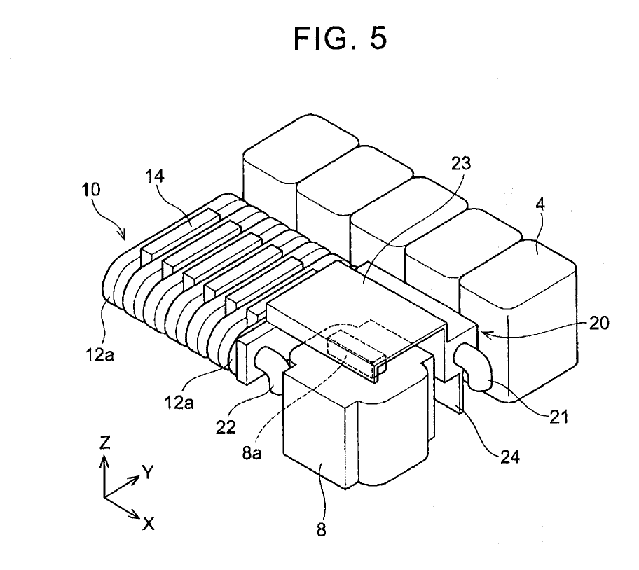

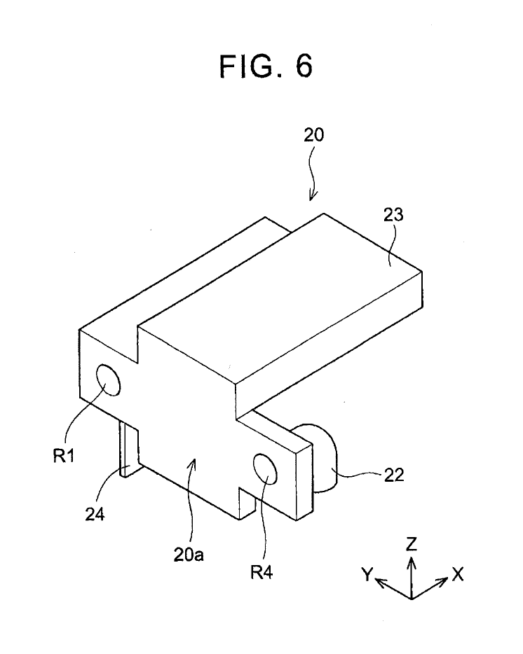

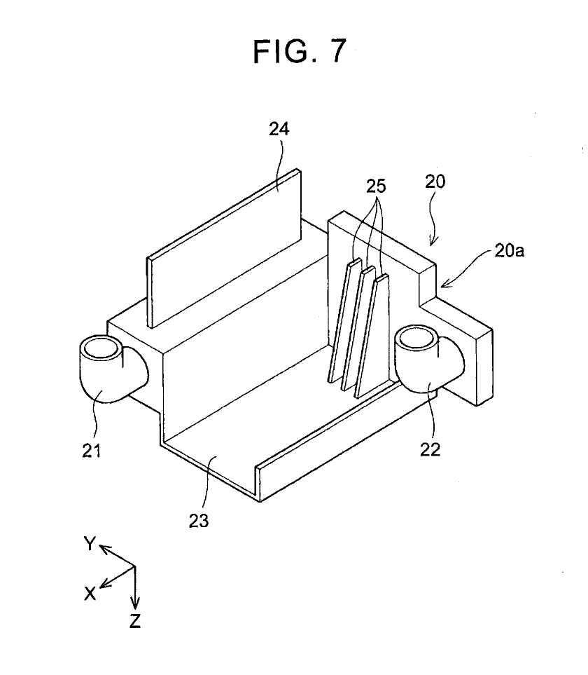

A hardware configuration of the power conversion device 2 will be described. FIG. 2 shows a plan view of the power conversion device 2. A reference numeral 3 denotes a housing of the power conversion device 2. Main components disposed in the housing are a capacitor module 4, a laminated unit 10, the reactor 8, and a cooling block 20. A configuration of the cooling block 20 will specifically be described below with reference to a perspective view showing arrangement of the components (FIG. 5) and perspective views of the cooling block 20 as seen from other angles (FIGS. 6 and 7).

The capacitor module 4 includes capacitors 52, 53 on the circuit of FIG. 1. Specifically, a plurality of capacitor elements are gathered in the capacitor module 4. A portion thereof corresponds to the above-described capacitor 52, and the remainder corresponds to the capacitor 53.

The laminated unit 10 is a device in which the semiconductor elements operating on the output current of the battery are integrated. Specifically, in the laminated unit 10, a plurality of flat-plate semiconductor modules 14 that are the semiconductor elements molded with a resin and a plurality of flat-plate cooling plates 12 are laminated together. In the single semiconductor module 14, single and sets of several transistors and diodes (see FIG. 1) contained in the above-described booster circuit 54 and the inverter circuit 55 are each molded with the resin. A coolant passes through the interior of the cooling plate 12. Both sides of the cooling plates 12 contact and cool the semiconductor module 14. The adjoining cooling plates 12 are connected by two connection pipes 13a, 13b, The coolant is supplied through the one connection pipe 13a and is discharged through the other connection pipe 13b. The laminated unit 10 has the plurality of semiconductor modules, the plurality of cooling plates, and the plurality of connection pipes; however, FIG. 2 does not show reference numerals and symbols of portions of the semiconductor modules, the cooling plates, and the connection pipes.

The laminated unit 10 is interposed and supported between a wall surface of the housing 3 and the cooling block 20. A plate spring 5 is inserted between the wall surface of the housing 3 and the laminated unit 10. The laminated unit 10 is pressurized in its laminating direction by the plate spring 5. The pressure in the laminating direction makes the semiconductor modules 14 and the cooling plates 12 that adjoin each other tightly fit together. This enhances heat transmission efficiency between the semiconductor modules 14 and the cooling plates 12.

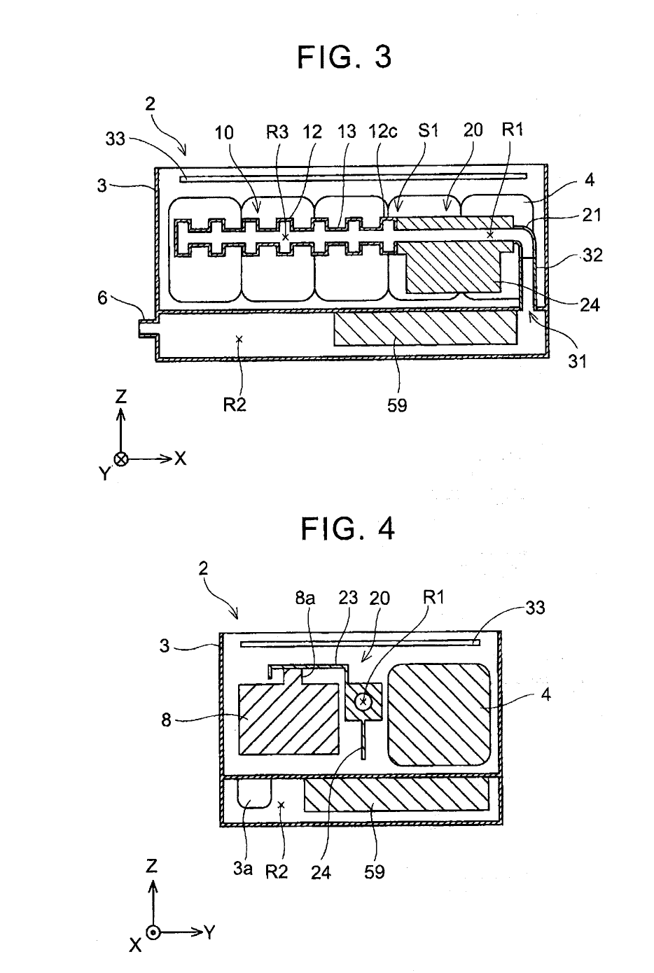

FIG. 3 shows a cross section taken along line in FIG. 2, and FIG. 4 shows a cross section taken along line IV-IV in FIG. 2. A rectangle denoted by a reference numeral 33 in FIGS. 3 and 4 represents a control board. The control circuit of the booster circuit 54 and the inverter circuit 55 are implemented in a control board 33. FIG. 2 does not show the control board 33, a support structure between the reactor 8 and the housing 3. As shown in FIG. 4, the cooling block 20 corresponds to a coupling section of an upper plate 23 and a side plate 24. The upper plate 23 is positioned between the reactor 8 and the control board 33 above the reactor 8. The side plate 24 is positioned between the reactor 8 and the capacitor module 4 on a lateral side of the reactor 8. The upper plate 23 and the side plate 24 are integrated with the cooling block 20, formed of aluminum. Thus, the upper plate 23 and the side plate 24 are cooled by the coolant passing through a passage R1. The upper plate 23 blocks the heat of the reactor 8 so as to prevent the heat of the reactor 8 from influencing the control board 33. Similarly, the side plate 24 blocks the heat of the reactor 8 so as to prevent the heat of the reactor 8 from influencing the capacitor module 4. The cooling block 20, the upper plate 23 and the side plate 24 regarded as a shield. See FIG. 3 for the side plate 24. The cooling block 20 corresponds to the coupling section of the upper plate 23, the side plate 24. The cooling block 20 regarded as a portion of the “shield”; however, an expression of “block” will be used for convenience of description.

A protrusion 8a provided on an upper surface of the reactor 8 contacts the upper plate 23. The heat of the reactor 8 is actively absorbed by the upper plate 23 via the protrusion 8a (that is, the cooling block 20 absorbs the heat via the protrusion 8a and the upper plate 23). The upper plate 23 is fixed to the reactor 8 by the protrusion 8a. That is, the cooling block 20 is fixed to the reactor 8 via the upper plate 23 and the protrusion 8a.

The cooling block 20 is supported by the reactor 8, and the reactor 8 is fixed to the housing 3. The cooling block 20 supports one end of the laminated unit 10 in the laminating direction. Specifically, the cooling block 20 directly contacts a cooling plate 12a positioned in one end section of the laminated unit 10 and thereby supports the laminated unit 10. Passages of the coolant are formed in the interior of the cooling block 20. The coolant supplied from the outside first passes through a space (described below) below the housing 3 and next the cooling block 20 and moves to the laminated unit 10. The coolant after cooling the semiconductor modules 14 in the laminated unit again passes through the cooling block 20 and then the space below the housing 3 and is discharged to the outside of the housing. The cooling block 20 is formed of aluminum or copper and transmits the heat of the reactor 8 contacting that to the coolant. In other words, the cooling block 20 cools the reactor 8. As described above, the cooling block 20 is also a portion of the “shield”.

The passage of the coolant will be described with reference to FIGS. 3 and 4. The coolant is supplied from a coolant supply opening 6 and discharged from a coolant discharge opening 7. As shown in FIGS. 3 and 4, the housing 3 is split into two spaces that are upper and lower spaces. FIG. 2 shows component arrangement in the upper space. The buck converter 59 is disposed in the lower space, and the coolant flows through a space R2 around the buck converter 59. The coolant supply opening 6 is connected to the lower space R2, and the coolant entering from the coolant supply opening 6 first cools the buck converter 59 in the space R2. The coolant next moves to the upper space through a connection hole 31 that connects the upper and lower spaces of the housing 3 together. One end of a coolant pipe 32 is connected to the connection hole 31, and the other end of the coolant pipe 32 is connected to an elbow pipe 21 that forms a portion of the cooling block 20. The coolant that has moved to the upper space passes through the coolant pipe 32 and the elbow pipe 21 and moves to the interior of the cooling block 20. The coolant passage R1 is formed in the interior of the cooling block 20. The coolant passage R1 opens on one surface (a unit support surface 20a described below) of the cooling block 20. The laminated unit 10 tightly fits on the unit support surface 20a. The coolant passage R1 is connected to an opening of the cooling plate 12a (see FIG. 2) in the end section of the laminated unit 10. The coolant that has passed through the coolant passage R1 flows into the cooling plate 12a of the laminated unit 10 and is next spread to all the cooling plates 12 contained in the laminated unit 10 via the connection pipe 13a. A reference symbol R3 in FIG. 3 denotes a coolant passage in the cooling plates 12.

The coolant that has passed through the cooling block 20 is supplied to the laminated unit 10. The coolant that has passed through the cooling plates 12 again returns to the cooling block 20. The coolant that has returned to the cooling block 20 moves to the lower space through the elbow pipe 22 that forms the portion of the cooling block 20. A section denoted by a reference symbol 3a in FIG. 4 represents a passage through which the returned coolant passes in the lower space. The section denoted by the reference symbol 3a is referred to as “discharge passage”. The coolant that has returned to the lower space passes through the discharge passage 3a and is discharged to the outside of the housing through the coolant discharge opening 7.

As described above, in the power conversion device 2, the entering coolant cools the buck converter 59 on a lower side of the housing 3 and next moves to the cooling block 20. The coolant cools the reactor 8 in the cooling block 20 and blocks the heat of the reactor 8 so as to prevent the heat from influencing the control board 33 and the capacitor module 4. The shield (the upper plate 23, the side plate 24, and the cooling block 20) contribute to the heat blockage. The coolant thereafter moves to the laminated unit 10 and cools the semiconductor elements in the semiconductor modules 14. As described above, in the power conversion device 2, the coolant is allowed to move to various places, thereby cooling the plurality of components.

A configuration of the cooling block 20 that is the portion of the shield will next be described in detail. FIG. 5 is a perspective view showing arrangement of the laminated unit 10, the reactor 8, the cooling block 20, and the capacitor module 4. FIG. 5 shows sections that are covered by the cooling block 20 and difficult to be seen in the reactor 8 with broken lines for easy understanding of the positional relationship between the cooling block 20 and the reactor 8. The other components are concealed by hidden line removal. As specifically shown in FIG. 5, the side plate 24 is positioned between the reactor 8 and the capacitor module 4.

FIG. 6 is a perspective view of the cooling block 20 as seen from another direction. FIG. 6 is a perspective view of the cooling block 20 as seen from a substantially opposite direction of the point of view of FIG. 5. A unit support surface 20a is flat and supports the laminated unit 10. That is, the cooling plate 12a in the end section of the laminated unit 10 in the laminating direction directly contacts the unit support surface 20a. End sections of coolant passages R1 and R4 open on the unit support surface 20a. The openings communicate with openings on an end surface of the cooling plate 12a positioned at the end of the laminated unit 10. The coolant discharged from the laminated unit 10 passes through the coolant passage R4.

FIG. 7 is a perspective view of the cooling block 20 as seen from yet another point of view. FIG. 7 corresponds to a view of the cooling block 20 as seen from the back side. Three ribs 25 are provided on a back side of the upper plate 23 and reinforce the upper plate 23.

Points to be noted about the technique described in the embodiment will be described. The technique disclosed in this specification is particularly characterized in the shield. The shield includes the cooling block 20, the upper plate 23 and the side plate 24. One of the characteristics is as follows. The coolant passes through the cooling block 20, and the cooling block 20 contacts and cools the reactor 8. At the same time, the cooling block 20 integrated with the upper plate 23, the side plate 24. The upper plate 23 and the side plate 24 extend between the reactor 8 and the other electronic components and thereby reduces an influence of the heat of the reactor 8 on the other electronic components. Typical examples of the other electronic components are the control board 33 and the capacitor module 4. In particular, the capacitor does not have high heat resistance, and the shield disclosed in this specification is thus effective. The cooling block 20 corresponds to the coupling section of the plurality of plates (the upper plate 23, the side plate 24) and serves as the portion of the shield.

The coolant passages are formed in the interior of the cooling block 20 that is the portion of the shield. In other words, the coolant passages that supply to or discharge from the laminated unit 10 pass through the interiors of the shield.

The coolant passages in accordance with the present invention include the supply pipe of coolant 13a, the discharge pipe of coolant 13b, the elbow pipe 21, and the coolant pipe 32 and serve as a generic name of a pipe through which the coolant passes. A portion of the coolant passages in accordance with the present invention may integrally be formed with the shield. For example, the portion of the coolant passages and the shield can integrally be fabricated by injection molding or the like with aluminum. In addition, the “shield” is not limited to a simple flat plate.

In the foregoing, specific examples of the present invention have been described in detail. However, those are merely illustrative and do not limit the claims. Techniques recited in the claims include modifications and variations of the specific examples described above. Technical elements described in this specification and the drawings provide technical usefulness by themselves or in various combinations and are not limited to the combinations recited in the claims in the application. Further, the techniques exemplified in this specification or the drawings can simultaneously achieve a plurality of objects, and achievement of a single object among those provides technical usefulness.

What is claimed is:

1. A power conversion device comprising:
a laminated unit in which flat-plate semiconductor modules and flat-plate cooling plates are laminated, the flat-plate semiconductor modules housing semiconductor elements;
a reactor; and
a shield interposed between the reactor and electronic components, the shield having coolant passages which supply coolant to or discharge coolant from the laminated unit through the shield.

2. The power conversion device according to claim 1,
wherein a portion of the coolant passages is integral with the shield.

3. The power conversion device according to claim 1,
wherein the shield contacts an end surface of the laminated unit in a laminating direction.

4. The power conversion device according to claim 1, wherein the shield includes a plurality of plates that are coupled together.

5. The power conversion device according to claim 1, wherein the shield contacts the reactor.

6. The power conversion device according to claim 1, wherein
the electronic components are a capacitor module and a control board, and
the shield is a cooling block, the cooling block includes an upper plate and a side plate, the cooling block has the coolant passages which supply coolant to or discharge coolant from the laminated unit, the upper plate is interposed between the reactor and the control board, and the side plate is interposed between the reactor and the capacitor module.
